(19) United States
(12) Patent Application Publication
(10) Pub. No.: US 2026/0026278 A1
(43) Pub. Date: Jan. 22, 2026

(54) METHODS FOR PROCESSING A MICROELECTRONIC DEVICE STRUCTURE AND RELATED SYSTEMS

(71) Applicant: Micron Technology, Inc., Boise, ID (US)

(72) Inventors: Kye Hyun Baek, Boise, ID (US); Tom J. John, Boise, ID (US)

(21) Appl. No.: 19/240,704

(22) Filed: Jun. 17, 2025

Related U.S. Application Data
(60) Provisional application No. 63/672,655, filed on Jul. 17, 2024.

(51) Int. Cl. H01L 21/311; H01J 37/32

(52) U.S. Cl. CPC H01L 21/31116; H01J 37/3244; H01J 37/32642; H01J 37/32724; H01J 2237/2007; H01J 2237/334

(57) ABSTRACT

A method of processing a microelectronic device structure comprises disposing a microelectronic device structure comprising one or more materials in a processing system. A coolant is introduced proximal to the microelectronic device structure and to a focus ring adjacent to the microelectronic device structure. One or more etch gas precursors are introduced into the processing system and the etch gas precursors are excited to generate one or more etch plasmas. One or more of the etch plasmas exhibit a different diffusivity coefficient than other of the etch plasmas. An inner region of the microelectronic device structure is exposed to at least one etch plasma and an outer region is exposed to at least one other etch plasma. The at least one etch plasma exhibits a diffusivity coefficient less than or equal to a diffusivity coefficient of the at least one other etch plasma. At least a portion of one or more materials of the microelectronic device structure is removed to form high aspect ratio openings and high aspect ratio features are formed in the high aspect ratio openings.

### CROSS-REFERENCE TO RELATED APPLICATIONS

This application claims the benefit under 35 U.S.C. § 119 (e) of U.S. Provisional Patent Application Ser. No. 63/672,655, filed Jul. 17, 2024, the disclosure of which is hereby incorporated herein in its entirety by this reference.

### TECHNICAL FIELD

This disclosure relates to a method and system for manufacturing a microelectronic device structure. More specifically, the disclosure relates to a method and system for etching a microelectronic device structure.

### BACKGROUND

Fabrication of a microelectronic device structure, particularly a memory device (e.g., NAND, DRAM, etc.) requires forming high aspect ratio (HAR) features in the microelectronic device structure. To form HAR features in the microelectronic device structure, high aspect ratio openings are formed in the microelectronic device structure and then the HAR openings are filled with one or more materials. Forming HAR openings in the microelectronic device structure involves removing (e.g., etching) of one or more materials formed in microelectronic device structure. Dry etching is a conventional method utilized in etching microelectronic device structures and includes etching using radical species generated in a beam of plasma. The radical species travel from a showerhead in a processing system and upon contact with the microelectronic device structure, remove one or more materials in the microelectronic device structure.

The semiconductor industry strives to develop memory devices with high storage capacity. One method to increase the storage capacity of a memory device is to increase the aspect ratio in HAR features in a microelectronic device structure of the memory device by increasing a depth of HAR openings. However, forming HAR openings in an outer region (e.g., edge) of a microelectronic device structure remains a challenge. Due to low performance of conventional dry etching methods, a desired depth of etch cannot be achieved in the outer region of the microelectronic device structure which results in misalignment of a bottom of the HAR openings. Low etch performance also results in twisting of HAR openings, especially in the outer region of the microelectronic device structure.

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIG. 1 is a simplified schematic of a system for processing a microelectronic device structure.

FIG. 2 is a simplified flow diagram of a method of processing a microelectronic device structure.

FIG. 3 is a simplified cross-sectional view of a microelectronic device structure.

FIG. 4 is a simplified cross-sectional view of a microelectronic device structure processed using the method of the disclosure.

FIG. 5 is a diagram of a temperature of a microelectronic device structure and a focus ring vs. pressure of a coolant in a cooling system of the processing system of the disclosure.

FIG. 6 is a comparison between an outer region of a microelectronic device structure processed using the method of the disclosure and an outer region of a microelectronic device structure processed using a conventional etching method.

FIG. 7 is a comparison between a microelectronic device structure processed using the method of the disclosure and a microelectronic device structure processed using a conventional etching method.

FIG. 8 is a comparison between an outer region of a microelectronic device structure processed using the method of the disclosure and an outer region of a microelectronic device structure processed using a conventional etching method.

### DETAILED DESCRIPTION

The illustrations presented herein are not actual views of any particular microelectronic device structure or processing system, or any component thereof, but are merely idealized representations, which are employed to describe embodiments of the invention.

As used herein, the singular forms following “a,” “an,” and “the” are intended to include the plural forms as well, unless the context clearly indicates otherwise.

As used herein, the term “aspect ratio” means and includes a ratio of a depth of an opening to a width (e.g., diameter) of the opening. The width of the opening is measured proximate the opening. The aspect ratio of a high aspect ratio (HAR) opening may be greater than about 20:1, greater than about 30:1, greater than about 40:1, greater than about 50:1, greater than about 60:1, greater than about 70:1, greater than about 80:1, greater than about 90:1, or greater than about 100:1 at its final depth. In some embodiments, the HAR opening has an aspect ratio of greater than about 50:1 at its final depth. In other embodiments, the HAR opening has an aspect ratio of greater than about 80:1 at its final depth. In yet other embodiments, the HAR opening has an aspect ratio of greater than about 90:1 at its final depth. In yet still other embodiments, the HAR opening has an aspect ratio of greater than about 100:1 at its final depth.

As used herein, the term “substrate” means and includes a base material or construction upon which additional materials are formed. The substrate may be a semiconductor substrate, a base semiconductor layer on a supporting structure, a metal electrode, or a substrate having one or more materials, layers, structures, or regions formed thereon. The materials on the substrate may include, but are not limited to, semiconductive materials, insulating materials, conductive materials, etc. One or more materials may be thermally sensitive. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any microelectronic device structure or processing system, or components thereof, when utilized in a conventional manner. Furthermore, these terms may refer to an orientation of elements of any microelectronic device structure or processing system, or components thereof as illustrated in the drawings.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.).

The following description provides specific details, such as material types and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an etch tool for fabricating semiconductor devices or a complete description of a process flow for manufacturing such semiconductor devices. The structures described below do not form complete semiconductor device structures. Only those process acts and structures necessary to understand the embodiments described herein are described in detail below. Additional acts to form a complete system for an etch tool or a semiconductor device described herein may be performed by conventional techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

A system for processing a microelectronic device structure may be utilized to form more uniform HAR features in the microelectronic device that includes the microelectronic device structure. The system may include a plasma chamber, such as a plasma etch chamber. The system may comprise a process chamber, an electrostatic chuck positioned on a pedestal and a cooling system operably coupled to the electrostatic chuck. A temperature of the electrostatic chuck may be adjusted to maintain the temperature of the microelectronic device structure. The cooling system may be configured to maintain a temperature of the microelectronic device structure between about 20° C. and about 60° C. The cooling system may be configured to reduce a temperature difference (e.g., a gradient) between an outer region and a center region of the microelectronic device structure. The system may comprise a focus ring adjacent to the microelectronic device structure and having a gap between the focus ring and the microelectronic device structure when the microelectronic device structure is disposed on the electrostatic chuck. The cooling system may be configured to maintain a temperature of the focus ring between about 40° C. and about 160° C. The cooling system may also be used to decrease a temperature difference between the microelectronic device structure and the focus ring. The system may comprise a gas distribution showerhead positioned a distance above the electrostatic chuck. The gas distribution showerhead may comprise outer channels configured to align with an outer region of the microelectronic device structure when the microelectronic device structure is disposed on the electrostatic chuck. The gas distribution showerhead may comprise inner and middle channels configured to align with an inner region of the microelectronic device structure when the microelectronic device structure is disposed on the electrostatic chuck. The system may comprise side plenums configured to extend over the focus ring, the gap between the microelectronic device structure and the focus ring, and a portion of the microelectronic device structure. Therefore, the side plenums extend beyond the microelectronic device structure by extending over (e.g., vertically adjacent to) the focus ring and the gap.

According to embodiments disclosed herein, methods of processing (e.g., etching) a microelectronic device structure are disclosed. The microelectronic device structure may be processed by removing at least a portion of one or more materials of the microelectronic device structure to form features, such as HAR features, in HAR openings formed in the microelectronic device structure. The microelectronic device structure may be disposed or formed on the electrostatic chuck of the system (e.g., processing system) according to embodiments of the disclosure. A temperature difference between the microelectronic device structure and the focus ring may be decreased by maintaining the temperature of the microelectronic device structure between about 20° C. and about 60° C. and the temperature of the focus ring between about 40° C. and about 160° C. during the processing of the microelectronic device structure. Etch gas precursors, each exhibiting a different etch chemistry (e.g., different diffusivity coefficient) than the others, may be introduced into the processing system. The etch gas precursors may be selected such that a selective removal of one or more materials from the microelectronic device structure is facilitated. Different etch gas precursors are introduced proximal to different locations of the microelectronic device structure so that the inner regions and outer regions of the microelectronic device structure may be exposed to etch plasmas formed from the respective etch gas precursors. The etch gas precursors may be excited to generate the etch plasmas. The inner and outer regions of the microelectronic device structure may be exposed to the etch plasmas each of which exhibiting a different or similar diffusivity coefficient to the other etch plasmas. The inner region of the microelectronic device structure may be exposed to at least one etch plasma that exhibits a diffusivity coefficient that is less than or equal to at least one other etch plasma contacted with the outer region of the microelectronic device structure. The plasmas may selectively remove one or more materials of the microelectronic device structure to form the HAR openings in which the HAR features are ultimately formed.

The methods of processing the microelectronic device structure according to embodiments of the disclosure may increase etch rates of one or more materials, particularly in the outer region and an edge of the microelectronic device structure, which improves uniformity of etching between the outer and inner regions of the microelectronic device structure. Moreover, the methods of processing the microelectronic device structure according to embodiments of the disclosure may improve alignment between one or more materials of the microelectronic device structure and alignment of a bottom of the HAR openings. Additionally, the methods of processing the microelectronic device structure according to embodiments of the disclosure may reduce twisting and bowing in the HAR openings/HAR features formed in the microelectronic device structure.

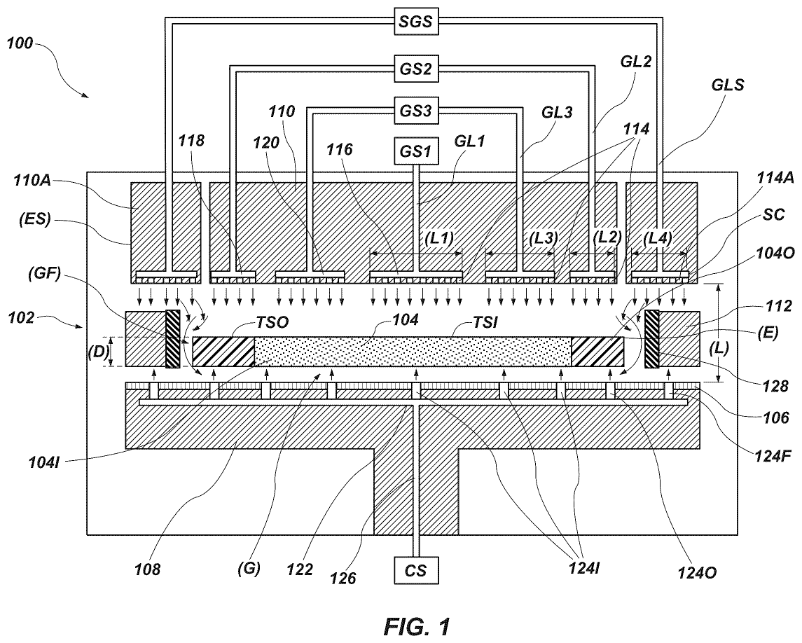

FIG. 1 shows a schematic illustration of a processing system 100, which also may be characterized as a so-called “etch tool” for performing processes according to embodiments of the disclosure on a microelectronic device structure 104. The processing system 100 may be used to form (e.g., deposit) one or more materials or to remove (e.g., etch) one or more materials of the microelectronic device structure. The processing system may, for example, be a plasma chamber, such as a plasma etch chamber. The processing system 100 may include a processing chamber 102 in which the microelectronic device structure 104 is disposed on a support structure, such as on an electrostatic chuck 106. The electrostatic chuck 106 may be positioned over a pedestal 108, a gas distribution showerhead 110 may be positioned a distance from the electrostatic chuck 106, a side plenum 110A may be adjacent to the gas distribution showerhead 110, and a focus ring 112 may be separated from the microelectronic device structure 104 by a gap (GF).

The microelectronic device structure 104 may include a base material or other construction upon which one or more materials, such as tiers of alternating materials, are formed. The microelectronic device structure 104 may be a base semiconductor material on a supporting substrate, or a substrate having one or more materials, structures, or regions formed thereon. The materials of the substrate may include, but are not limited to, semiconductive materials, insulating materials, conductive materials, etc.

The gas distribution showerhead 110, through apertures 114, facilitates the flow of etch gas precursors into the processing chamber 102 and onto the microelectronic device structure 104. The gas distribution showerhead 110, through gas lines (e.g., GL1, GL2, GL3, etc.), is in fluid connection with gas sources (e.g., GS1, GS2, GS3, etc.). The gas sources supply the gas distribution showerhead 110 with etch gas precursors which are subsequently introduced to the processing chamber 102.

The side plenum 110A, through apertures 114A, facilitates the flow of etch gas precursors into the processing chamber 102, onto the focus ring 112 and the microelectronic device structure 104, and into the gap (GF) between the microelectronic device structure 104 and the focus ring 112. The side plenum 110A, through a gas line GLS, is in fluid connection with a gas source SGS. The gas source SGS supplies the side plenum 110A with etch gas precursors which are subsequently introduced to the processing chamber 102.

The gas sources may include a first gas source GS1, a second gas source GS2, a third gas source GS3, and a side gas source SGS. The first gas source GS1, through the first gas line GL1, is in fluid connection with inner channels 116 positioned at a center of the gas distribution showerhead 110. The inner channels 116 extend a first length L1 from one edge to an opposing edge. The third gas source GS3, through the third gas line GL3, is in fluid connection with middle channels 120 positioned adjacent to the inner channels 116. The middle channels 120 extend a third length L3 between one edge and an opposing edge. The second gas source GS2, through the second gas line GL2, is in fluid connection with outer channels 118 positioned between the middle channels 120 and an edge (ES) of the gas distribution showerhead 110. The outer channels 118 extend a second length L2 between one edge and an opposing edge. The side gas source SGS, through the side gas line GLS, is in fluid connection with side channels SC in the side plenum 110A. The side channels SC extend a fourth length L4 across the side plenum 110A.

In an alternative embodiment (not shown), the side plenum 110A may be incorporated into the gas distribution showerhead 110 such that the side channels SC are positioned between the outer channels 118 and the edge (ES) of the gas distribution showerhead 110.

The gas sources GS1, GS2, GS3, SGS are in fluid connection with the processing chamber 102 through channels 116, 120, 118, SC, apertures 114, 114A, and gas lines GL1, GL2, GL3, GLS. The size ratios of L1:L2:L3:L4 are not limited to any specific value and can be adjusted based on different operating parameters (e.g., dimensions of the microelectronic device structure 104 and the gas distribution showerhead 110, flow rate of gas, etch rate, etch depth, etc.).

The side channels SC of the side plenum 110A may be aligned with (e.g., vertically adjacent to) the focus ring 112. The inner and middle channels 116, 120 may be aligned with (e.g., vertically adjacent to) an inner region 104I of the microelectronic device structure 104 and the outer channels 118 may be aligned with (e.g., vertically adjacent to) an outer region 104O of the microelectronic device structure 104.

The gas distribution showerhead 110 may, alternatively, comprise fewer channels (not shown), such as inner and outer channels 116, 118. The gas sources may include first and second gas sources GS1, GS2. The first gas source GS1, through the first gas line GL1, is in fluid connection with the inner channels 116 positioned at a center of the gas distribution showerhead 110. The inner channels 116 extend a first length L1 between one edge and an opposing edge. The second gas source GS2, through the second gas line GL2, is in fluid connection with the outer channels 118. The outer channels 118 are positioned between the inner channels 116 and the edge (ES) of the gas distribution showerhead 110 and extend a second length L2 between one edge and an opposing edge. The gas sources GS1, GS2 are in fluid connection with processing chamber 102 through channels 116, 118, apertures 114, and gas lines GL1, GL2.

The pedestal 108 may include a cooling system 122 in heat flow communication with the electrostatic chuck 106/pedestal 108. The cooling system 122 may comprise inner apertures 124I, outer apertures 124O, and focus ring apertures 124F in fluid connection with a coolant source CS through a coolant channel 126. The inner, outer, and focus ring apertures 124I, 124O, 124F extend from the pedestal 108 through the electrostatic chuck 106. The cooling system 122 may be configured to align the inner apertures 124I with the inner region 104I of the microelectronic device structure 104, the outer apertures 124O with the outer region 104O of the microelectronic device structure 104, and the focus ring apertures 124F with the focus ring 112. The position of the apertures 124I, 124O, 124F of the cooling system 122 relative to the microelectronic device structure 104 and the focus ring 112 may be adjusted based on operating parameters (e.g., temperature, pressure, and flow) of a coolant flowing in the cooling system 122. The processing chamber 102, apertures 124I, 124O, 124F, coolant channel 126, and coolant source CS are in fluid connection with one another. The cooling system 122 may be configured to reduce a difference in temperature between the outer region 104O and a center of the microelectronic device structure 104. The cooling system 122 may also be configured to reduce a difference in temperature between the outer region 104O of the microelectronic device structure 104 and the focus ring 112, particularly a difference in temperature between the outer region 104O of the microelectronic device structure 104 and a body 128 of the focus ring 112.

The cooling system 122 may be configured to maintain a temperature of the microelectronic device structure 104 between about 20° C. and about 60° C. The cooling system 122 may also be configured to maintain a temperature of the focus ring 112 between about 40° C. and about 160° C. The coolant may comprise helium or another gas. Although FIG. 1 is illustrated and described as including the cooling system 122 in the processing chamber 102, the disclosure is not so limited. An additional cooling system (not shown) may be internal to the pedestal and in closed loop fluid communication with a heat exchanger. The circulation of an additional coolant in the additional cooling system reduces the temperature of the coolant (e.g., helium), electrostatic chuck/microelectronic device structure and the focus ring. In such embodiments, the additional coolant may include ice water, a chilled brine solution, liquid carbon dioxide, liquid nitrogen, helium, or another material.

The focus ring 112 may be adjacent (e.g., laterally adjacent) to the microelectronic device structure 104 and separated by the gap (GF) from the microelectronic device structure 104, when the microelectronic device structure 104 is disposed on the electrostatic chuck 106.

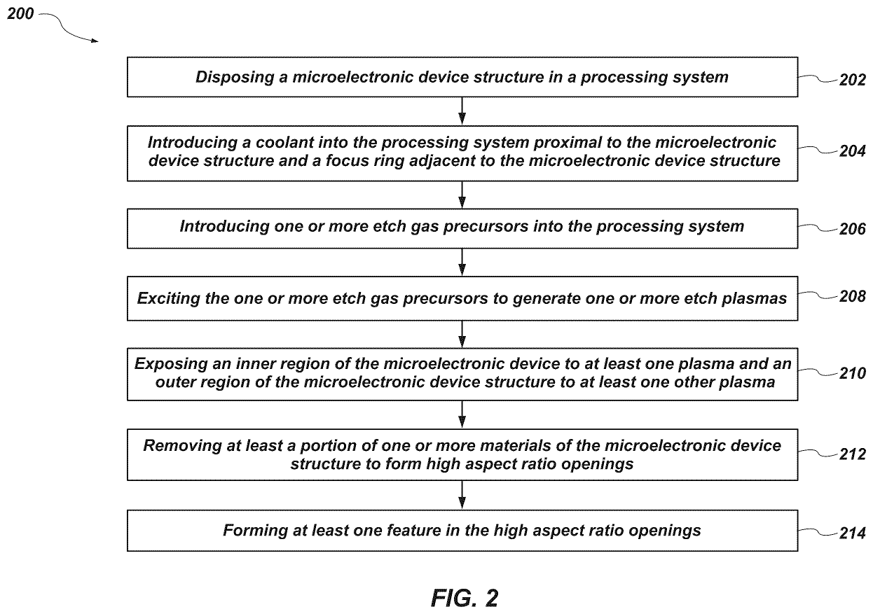

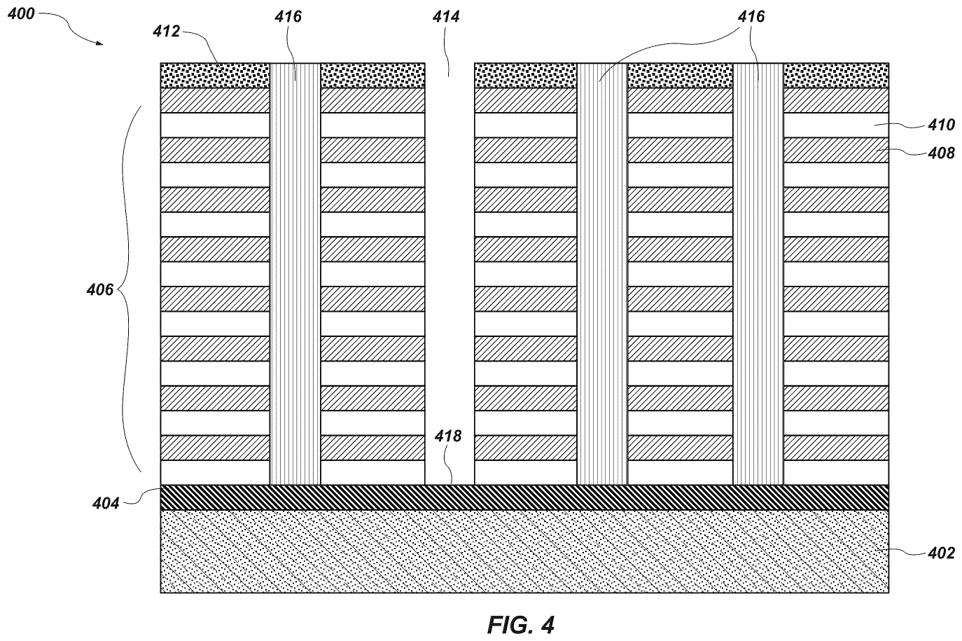

FIG. 2 illustrates a simplified flow diagram of a method 200 of processing a microelectronic device structure 400 (FIG. 4). The method 200 may comprise act 202 including disposing a microelectronic device structure in a processing system; act 204 including introducing a coolant into the processing system proximal to the microelectronic device structure and a focus ring adjacent to the microelectronic device structure; act 206 introducing one or more etch gas precursors into the processing system; act 208 exciting the one or more etch gas precursors to generate one or more etch plasmas; act 210 including exposing an inner region of the microelectronic device structure to at least one etch plasma and an outer region of the microelectronic device structure to at least one other etch plasma; act 212 including removing at least a portion of one or more materials of the microelectronic device structure to form high aspect ratio openings in the microelectronic device structure; act 214 including forming at least one feature in the high aspect ratio openings in the microelectronic device structure.

Act 202 may include disposing the microelectronic device structure 104 (e.g., semiconductor device structure 300) in the processing system 100. The microelectronic device structure 104 may include one or more materials to be etched or otherwise processed. By way of example only, the microelectronic device structure 104 may include materials through which HAR openings 414 are to be formed. Alternatively, disposing the microelectronic device structure 104 in the processing system 100 may comprise forming materials of the microelectronic device structure 300 on the electrostatic chuck 106. The materials may be formed by conventional techniques.

Act 204 may include introducing a coolant into the processing system 100 proximal to the microelectronic device structure 104 and the focus ring 112 adjacent to the microelectronic device structure 104. The coolant may flow onto and around the microelectronic device structure 104 and the focus ring 112 adjacent to the microelectronic device structure 104. The coolant, supplied from the coolant source CS, effluxes from inner and outer apertures 124I, 124O, passes across a gap (G) between the electrostatic chuck 106 and the microelectronic device structure 104, as indicated by the arrows, and exchanges heat with the microelectronic device structure 104, reducing a temperature of the microelectronic device structure 104. The coolant also effluxes from focus ring apertures 124F and flows onto and around the focus ring 112, as indicated by the arrows, and exchanges heat with the focus ring 112, particularly with the body 128 of the focus ring 112. The coolant also flows onto the inner and outer regions 104I, 104O of the microelectronic device structure 104. The heat exchange between the coolant and the focus ring 112 results in a reduction in temperature of the focus ring 112 relative to the temperature of the microelectronic device structure 104. More particularly, a temperature of the body 128 of the focus ring 112 may be reduced relative to the temperature of the microelectronic device structure 104. Since the microelectronic device structure 104 may be constantly contacted with the coolant, the heat exchange between the coolant and the microelectronic device structure 104 maintains the temperature of the microelectronic device structure 104 in a pre-determined range. Accordingly, reducing the temperature of the focus ring 112 or the body 128 of the focus ring 112 may reduce a temperature difference between the focus ring 112 and the microelectronic device structure 104. The coolant also exchanges heat with the inner and outer regions 104I, 104O of the microelectronic device structure 104 which reduces a temperature difference between the inner and outer regions 104I, 104O of the microelectronic device structure 104.

By way of nonlimiting example, a temperature of the additional coolant may be between about −100° C. and about 0° C., such as between about −100° C. and about −30° C., between about −80° C. and about 0° C., between about −60° C. and about 0° C., between about −40° C. and about 0° C., between about −80° C. and about −40° C., between about −80° C. and about −50° C., between about −80° C. and about −60° C., between about −60° C. and about −40° C., between about 40° C. and about −20° C., or between about −20° C. and about 0° C.

A pressure of the coolant in the cooling system 122 may be between about 5 Torr and about 65 Torr, such as between about 5 Torr and about 15 Torr, between about 15 Torr and about 25 Torr, between about 25 Torr and about 35 Torr, between about 35 Torr and about 45 Torr, between about 45 Torr and about 50 Torr, or between about 55 Torr and about 65 Torr.

In some embodiments, the temperature of the additional coolant and the pressure of the coolant in the cooling system 122 are about −30° C. and about 40 Torr, respectively.

By way of nonlimiting example, the temperature of the microelectronic device structure 104 during the processing may be maintained between about 20° C. and about 60° C., such as between about 20° C. and about 30° C., between about 30° C. and about 40° C., between about 40° C. and about 50° C., or between about 50° C. and about 60° C., and the temperature of the focus ring 112 and/or the body 128 of the focus ring 112 during the processing may be maintained between about 40° C. and about 160° C., such as between about 40° C. and about 60° C., between about 60° C. and about 80° C., between about 80° C. and about 100° C., between about 100° C. and about 120° C., between about 120° C. and about 140° C., and between about 120° C. and about 160° C.

An increase in the pressure of coolant within the processing chamber 102 results in a decrease between the temperatures of the microelectronic device structure 104 and the focus ring 112. In other words, the temperature difference between the microelectronic device structure 104 and the focus ring 112 may be reduced by increasing the pressure of the coolant within the processing chamber 102.

It is believed that reducing the temperature difference between the microelectronic device structure 104 and the focus ring 112 results in an increase in etch rate and etch uniformity in the outer region 104O of the microelectronic device structure 104. Particularly, reducing the temperature difference between the outer region 104O of the microelectronic device structure 104 and the body 128 of the focus ring 112 results in an increase in etch rate and/or etch uniformity in the outer region 104O of the microelectronic device structure 104. It is also believed that reducing the temperature difference between the inner and outer regions 104I, 104O of the microelectronic device structure 104 results in an increase in etch rate and etch uniformity in the outer region 104O of the microelectronic device structure 104.

Act 206 includes introducing one or more etch gas precursors into the processing system 100. The etch gas precursors flow from gas sources GS1, GS2, GS3, SGS into the gas distribution showerhead 110 and the side plenum 110A. Each of the etch gas precursors may be selected depending on the materials of the microelectronic device structure to be removed. The etch gas precursors may be introduced to an upper portion of the processing chamber 102, through the gas distribution showerhead 110, or to a side portion of the processing system 100, through the side plenum 110A in a side portion of the processing chamber 102 and above the focus ring 112. The etch gas precursors may be introduced into the processing chamber 102 at different locations, such as proximal to the inner region 104I of the microelectronic device structure 104, proximal to the outer region of the microelectronic device structure 104, or proximal to the focus ring 112.

By way of nonlimiting example, the etch gas precursors may include, but are not limited to, hydrogen gas (H₂), chlorine gas (Cl₂), a fluorocarbon (e.g., C₄F₆, C₄F₈, C₅F₈), a hydrofluorocarbon (e.g., CH₂F₂, C₄H₂F₆), SF₆, NF₃, HBr, or a combination thereof. The etch gas precursor may exhibit a molecular weight of greater than about 55. The fluorocarbon may comprise a constituent with a chemical formula of CₓF_{y} (x=1-4, and y=1-8). The hydrofluorocarbon may comprise a constituent with a chemical formula of CₙHₓF₍₂ₙ₊₂₋ₓ₎ (n=1-4, and x=1-4). However, other etch gas precursors may be used depending on the material(s) to be removed.

The etch gas precursors introduced into the processing chamber 102 may exhibit different diffusion coefficients, with the diffusion coefficient of each of the etch gas precursor selected based on the location within the processing chamber 102 in which the etch gas precursor is introduced. The diffusion coefficient of the etch gas precursor is related to the molecular weight of the etch gas precursor. A less diffusive gas may exhibit a molecular weight of greater than or equal to about 140 and a more diffusive gas may exhibit a molecular weight of less than 140. A diffusion coefficient D₁ of a first etch gas precursor introduced proximal to the inner region 104I of the microelectronic device structure 104 may be less than or equal to a diffusion coefficient D₂ of a second etch gas precursor (e.g., D₁≤D₂) introduced proximal to a middle region of the microelectronic device structure 104, the diffusion coefficient D₂ of the second etch gas precursor may be less than or equal to a diffusion coefficient D₃ of a third etch gas precursor (e.g., D₁≤D₂≤D₃) introduced proximal to the outer region 104O of the microelectronic device structure 104, and the diffusion coefficient D₃ of the third etch gas precursor may be less than or equal to a diffusion coefficient D_{S} of an etch gas precursor (e.g., D₁≤D₂≤D₃≤D_{S}) introduced proximal to the focus ring 112. In an alternative embodiment, the diffusion coefficient D_{S} of the side etch gas precursor may be less than or equal to the diffusion coefficient D₃ of the third etch gas precursor (e.g., D₁≤D₂≤D_{S}≤D₃).

The first etch gas precursor, through inner channels 116, may be introduced proximal to the inner region 104I of the microelectronic device structure 104, particularly, proximal to a center region of the microelectronic device structure 104 positioned at a center of the inner region 104I of the microelectronic device structure 104. The second etch gas precursor, through middle channels 120, may be introduced proximal to a middle portion of the inner region 104I of the microelectronic device structure 104, particularly proximal to a middle region of the microelectronic device structure 104 positioned in the inner region 104I of the microelectronic device structure 104 between the center region and the outer region 104O of the microelectronic device structure 104. The third etch gas precursor, through outer channels 118, may be introduced proximal to the outer region 104O of the microelectronic device structure 104. The side etch gas precursor, through side channels SC, may be introduced proximal to the focus ring 112, and into the gap (GF). In some particular embodiments, the side etch gas precursor may be introduced proximal to the focus ring 112 and flow through the gap (GF) and around the outer region 104O of the microelectronic device structure 104.

In an alternative embodiment, the first etch gas precursor exhibiting the diffusivity coefficient D₁ is introduced proximal to the inner region 104I of the microelectronic device structure 104. The inner channels 116 are sized and aligned such that the first etch gas precursor flows onto and contacts the inner region 104I of the microelectronic device structure 104. The third etch gas precursor exhibiting the diffusivity coefficient D₃, through outer channels 118, is introduced proximal to the outer region 104O of the microelectronic device structure 104. The outer channels 118 are sized and aligned such that the third etch gas precursor flows onto and contacts the outer region 104O of the microelectronic device structure 104. The side etch gas precursor exhibiting the diffusivity coefficient D_{S} is introduced proximal to the focus ring 112. The side channels SC are sized and aligned such that the side etch gas precursor flows onto and contacts the focus ring 112 and the outer region 104O of the microelectronic device structure 104, and flows into the gap (GF). The diffusivity coefficients D₁, D₃, D_{S} are such that D₁≤D₃≤D_{S} or D₁≤D_{S}≤D₃.

Each etch gas precursor may constitute between about 0 volume percent and about 100 volume percent of a total gas composition introduced into the processing chamber 102, such as between about 0 volume percent and about 60 volume percent, between about 0 volume percent and about 40 volume percent, or between about 0 volume percent and about 20 volume percent of the total gas composition. The flow rate, pressure and temperature of each etch gas precursor may be adjusted based on the materials to be etched and desired etch rate, etch depth, alignment, etc.

Act 208 includes exciting the one or more etch gas precursors to generate one or more etch plasmas. The etch gas precursors are excited to form etch plasmas in the gas distribution showerhead 110 and the side plenum 110A. Methods of generating the etch plasmas are known in the art. The etch plasmas efflux into the processing chamber 102 from corresponding channels 116, 118, 120, and SC. A first etch plasma is generated by exciting the first etch gas precursor supplied from the first gas source GS1 into the inner channels 116. The first etch plasma effluxes into the processing chamber 102 through apertures 114 in the inner channels 116. A third etch plasma is generated by exciting the third etch gas precursor supplied from the second gas source GS2. The third etch plasma effluxes into the processing chamber 102 through apertures 114 in the outer channels 118. A second etch plasma is generated by exciting the second etch gas precursor supplied from the third gas source GS3. The second etch plasma effluxes into the processing chamber 102 through apertures 114 in the middle channels 120. A side etch plasma is generated by exciting the side etch gas precursor supplied from the side gas source SGS. The side etch plasma effluxes into the processing chamber 102 through apertures 114A in the SC channels and over the focus ring 112, in particular over the body 128 of the focus ring 112. The first, second, third, and side etch plasmas may exhibit similar or different chemical compositions from one another.

Alternatively, the etch plasmas efflux into the processing chamber 102 from corresponding channels 116, 120, and SC. The first etch plasma is generated by exciting the first gas precursor supplied from the first gas source GS1 into the inner channels 116. The first etch plasma effluxes into the processing chamber 102 through apertures 114 in the inner channels 116. The third etch plasma is generated by exciting the third etch gas precursor supplied from the second gas source GS2. The third etch plasma effluxes into the processing chamber 102 through apertures 114 in the outer channels 118. A side etch plasma is generated by exciting the side etch gas precursor supplied from the side gas source SGS. The side etch plasma effluxes into the processing chamber 102 through apertures 114A in the SC channels and over the focus ring 112, in particular over the body 128 of the focus ring 112. The first, third, and side etch plasmas may exhibit the same chemical composition or different chemical compositions from one another.

Although FIG. 1 is illustrated and described as generating the etch plasmas in the gas distribution showerhead 110 and the side plenum 110A, the disclosure is not so limited. The etch plasmas may be generated in the processing chamber 102. By way of nonlimiting example, in some embodiments, electrodes (e.g., cathode and anodes) (not shown) may be disposed in the processing chamber 102 and under the gas distribution showerhead 110 and the side plenum 110A. The etch gas precursors from the gas distribution showerhead 110 and the side plenum 110A may pass through the space between the electrodes and then become excited.

Act 210 includes exposing the inner region 104I of the microelectronic device structure 104 to at least one etch plasma and the outer region 104O of the microelectronic device structure 104 to at least one other etch plasma. The at least one etch plasma may comprise the first and second etch plasmas or, alternatively, only the first etch plasma. The at least one other etch plasma may comprise the third and side etch plasmas generated in act 208. The at least one etch plasma may flow between the gas distribution showerhead 110 and the microelectronic device structure 104 and contact the inner region 104I of the microelectronic device structure 104 on a top surface TSI of the inner region 104I of the microelectronic device structure 104 as indicated by the arrows (FIG. 1). The at least one other etch plasma may flow onto a top surface TSO of the outer region 104O of the microelectronic device structure 104 as indicated by arrows (FIG. 1).

With reference to FIG. 1, the gas distribution showerhead 110, the side plenum 110A and the microelectronic device structure 104 may be configured such that the inner and middle channels 116, 120 substantially align with the top surface TSI of the inner region 104I of the microelectronic device structure 104, the outer channels 118 substantially align with the top surface TSO of the outer region 104O of the microelectronic device structure 104, and the side channels SC substantially aligns with the focus ring 112 and the gap (GF). The at least one etch plasma may flow substantially onto the top surface TSI of the inner region 104I of the microelectronic device structure 104. The at least one other etch plasma may flow substantially onto the top surface TSO of the outer region 104O of the microelectronic device structure 104, into the gap (GF), and onto the focus ring 112.

During the process according to embodiments of the disclosure, plasma radicals are formed at an initial concentration, with radical species proximal to the focus ring 112 being present at a lower concentration compared to the radical species distal to the focus ring 112. The initial concentration of the radical species at the outer region 104O of the microelectronic device structure 104 may be less than at the center region of the microelectronic device structure 104, or relatively less than the inner region 104I of the microelectronic device structure 104. By decreasing the temperature difference between the focus ring 112 and the edge (E) of the microelectronic device structure 104, and the temperature difference between the inner and outer regions 104I, 104O of the microelectronic device structure 104, more particularly the temperature difference between the center region and the outer region 104O of the microelectronic device structure 104, the radical species may diffuse toward the focus ring 112, and increase the concentration of radical species in the outer region 104O and the edge (E) of the microelectronic device structure 104, and in the gap (GF). The increased concentration of radical species may increase the etch rate/etch depth in the outer region 104O of the microelectronic device structure 104 relative to the inner region 104I of the microelectronic device structure 104, thus enabling more uniform etching at the edge (E) and outer region 104O of the microelectronic device structure 104. By flowing side and outer plasmas over the edge (E) of the microelectronic device structure 104 and in the gap (GF), and around a thickness D of the microelectronic device structure 104, the radical species may diffuse toward the focus ring 112, and increase the concentration of radical species in the outer region 104O and the edge (E) of the microelectronic device structure 104, and in the gap (GF).

The first, second, third, and side etch plasmas may respectively exhibit diffusivity coefficients D₁, D₂, D₃, D_{S} wherein D₁≤D₂≤D₃≤D_{S} or D₁≤D₂≤D_{S}≤D₃. By flowing the etch plasmas with higher diffusivity coefficients onto the microelectronic device structure 104 and toward the focus ring 112, the more diffusive radical species may diffuse toward the focus ring 112 and into the outer region 104O and the edge (E) of the microelectronic device structure 104.

Although act 210 is described as exposing the inner region 104I of the microelectronic device structure 104 to at least one etch plasma (e.g., comprising the first and second etch plasmas wherein D₁≤D₂, or the first etch plasma D₁) and the outer region 104O of the microelectronic device structure 104 to at least one other etch plasma (e.g., comprising the third and side etch plasmas wherein D₁≤D₂≤D₃D_{S}), the disclosure is not so limited. In some embodiments, the outer region 104O of the microelectronic device structure 104 may be exposed to one or more etch plasmas exhibiting diffusivity coefficient(s) less than or equal to one or more other etch plasmas contacted with the inner region 104I of the microelectronic device structure 104. The order at which different regions of the microelectronic device structure 104 are exposed to the etch plasmas, wherein each etch plasma may exhibit a different diffusivity coefficient than other etch plasmas, may be adjusted based on desired etch rate/etch depth, alignment of the HAR openings, etc. The order of exposing the microelectronic device structure 104 to the etch plasmas may be changed in different cycles of an etch process based on desired etch rate/etch depth, alignment of the HAR openings, etc.

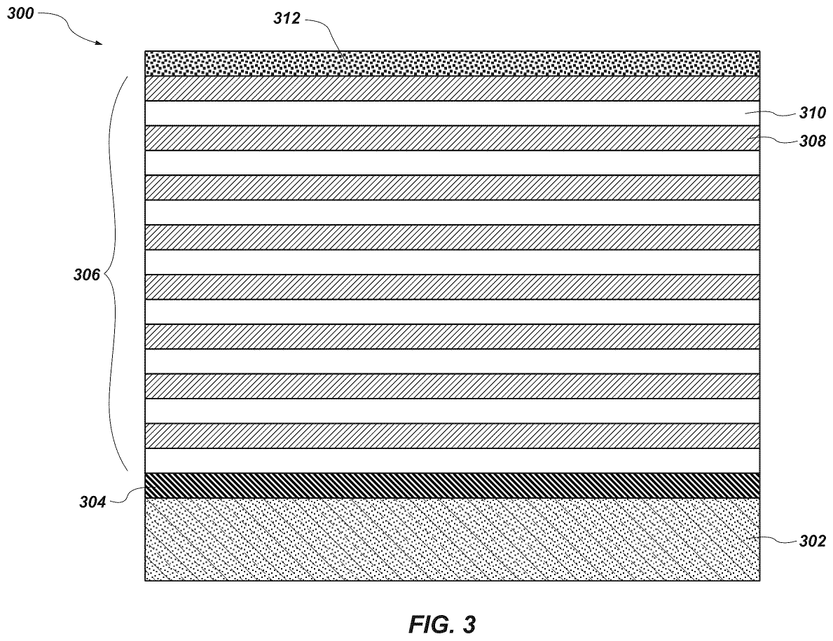

Act 212 includes removing at least a portion of one or more materials of the microelectronic device structure 104 (e.g., microelectronic device structure 300) to form high aspect ratio openings 414 in which features 416 are ultimately formed. The HAR openings 414 (FIG. 4) may, for example, be HAR openings in which HAR features are ultimately formed. With reference to FIGS. 1 and 3, the at least one and one other etch plasmas as in act 210 upon contact with the top surfaces TSI, TSO of the inner and outer regions 104I, 104O of the microelectronic device structure 104 diffuse into and remove (e.g., etch) one or more materials. Exposing the outer region 104O of the microelectronic device structure 104 to the at least one other etch plasma exhibiting a diffusivity coefficient greater than or equal to the at least one etch plasma, facilitates forming the HAR openings 414 that exhibit more uniform depth in the edge (E) and outer region 104O of the microelectronic device structure 104 and reduces twisting and bowing in the HAR openings 414 formed in the edge (E) and outer region 104O of the microelectronic device structure 104.

FIG. 3 illustrates a microelectronic device structure 300 that has been formed by conventional techniques. By way of example only, the microelectronic device structure 300 may comprise a substrate 302, optionally, an etch stop material 304, a stack 306 including tiers of alternating first and second materials 308, 310 formed over the substrate 302, and an etch mask material 312 formed over the stack 306. The etch stop material 304 may be aluminum oxide or other etch stop material selected such that portions of the tiers of alternating materials 308, 310 may be selectively removed without removing other materials of the microelectronic device structure 300. Any known dielectric, conductive, or semiconductive material may be used for the tiers of alternating materials 308, 310 (e.g., silicon nitride, silicon oxide, etc.). Any known material may be used for the etch mask material 312 (e.g., spin-on etch mask, organo-siloxane, carbon-based, carbon-silicon, nitride, metal, or metal oxide materials).

Act 214 includes forming at least one feature 416 in the high aspect ratio openings 414 in the microelectronic device structure 104 (e.g., semiconductor device structure 300). With reference to FIGS. 3 and 4, removing a portion of the alternating materials 308, 310 may form HAR openings 414 in the stack 406 following the exposure to the at least one and one other etch plasmas. Depending on the feature(s) 416 to be formed, one or more materials may be formed in the HAR openings 414.

FIG. 4 illustrates a microelectronic device structure 400 that has been at least partially formed by etching the microelectronic device structure 300 according to embodiments of the disclosure. With reference to FIG. 3, the etch mask material 312 may be patterned by conventional patterning techniques to form a patterned etch mask material 412 having openings that correspond to the location of HAR openings 414 to be formed in the microelectronic device structure 400. The patterned etch mask material 412 may be used to form the HAR openings 414 in the underlying stack 406. One or more materials may be formed in the HAR openings 414 to form HAR features 416 in the microelectronic device structure 400. By way of example only, a conductive material may be formed in the HAR openings 414. The methods according to embodiments of the disclosure are not limited to be performed on the microelectronic device structure 300 and may be conducted to form HAR openings and HAR features of other microelectronic device structures.

In a comparison between HAR openings of a microelectronic device structure formed utilizing a conventional method and HAR openings 414 of the microelectronic device structure 400 formed according to embodiments of the disclosure, the HAR openings 414 of the microelectronic device structure 400 may exhibit more uniform etching (e.g., more uniform etch depth) and more uniform alignment. By exposing the outer region 104O of the microelectronic device structure 300 to an etch plasma exhibiting a higher diffusivity coefficient than that to which the inner region 104I of the microelectronic device structure 300 is exposed, features formed in the HAR openings 414 of the microelectronic device structure 400 may exhibit better electrical performance.

In the methods of forming the microelectronic device structure 400 according to embodiments of the disclosure, similar or different flow rates of the side etch plasma may be utilized. In some embodiments, the flow rate of the side etch gas contacting the outer region of the microelectronic device structure 300 was equal to that of the side etch plasma contacting the outer region of the microelectronic device structure formed using the conventional method and in some other embodiments the flow rate of the side etch gas contacting the outer region of the microelectronic device structure 300 was different (e.g., relatively greater) than that of the side etch plasma contacting the outer region of the microelectronic device structure formed using the conventional method.

The outer region 104O of the microelectronic device structure 300 may be exposed to an etch plasma exhibiting a higher diffusivity coefficient than an etch plasma contacted with the inner region 104I of the microelectronic device structure 300, in contrast to outer and inner regions of the microelectronic device structure formed with the conventional method being exposed to similar etch plasmas (e.g., exhibiting similar diffusivity coefficients). The methods of processing the microelectronic device structure 300 according to embodiments of the disclosure may include controlling (e.g., reducing) the temperature difference between the focus ring and the microelectronic device structure 300.

At the outer region of the microelectronic device processed utilizing the conventional method, the formed openings may be underetched and the uniformity of the openings may decrease in that the openings are not etched to a uniform depth and the bottom of the openings are not aligned. The degree of nonuniformity of the openings formed by the conventional method increases at an increased distance (142 mm, 145 mm, 147 mm) from the center of the microelectronic device structure. Additionally, the openings may be twisted at an increased distance (145 mm, 147 mm) from the center of the microelectronic device and a remaining thickness of the etch mask may be nonuniform at an increased distance (145 mm, 147 mm) from the center of the microelectronic device structure. In contrast, in the microelectronic device structure 400 processed according to the methods of the disclosure, the depth of the HAR openings 414 in the outer region 104O of the microelectronic device structure 400 may be substantially more uniform at an increased distance (142 mm, 145 mm, 147 mm) from the center of the microelectronic device structure 400. In addition, the HAR openings 414 are less twisted at an increased distance (145 mm, 147 mm) from the center of the microelectronic device structure, and a relatively uniform thickness of the etch mask material 412 remains at an increased distance (145 mm, 147 mm) from the center of the microelectronic device structure.

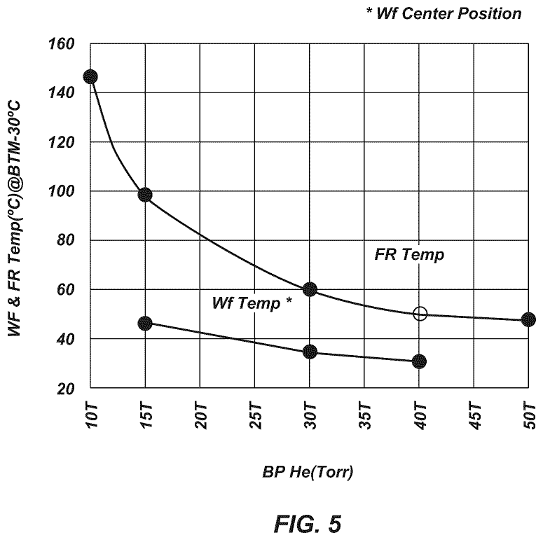

FIG. 5 illustrates profiles of the temperatures of the microelectronic device structure 104 and the focus ring 112 against the pressure of the coolant in the cooling system 122 of the processing system 100. As can be seen, an increase in the pressure of the coolant results in a decrease in temperature difference between microelectronic device structure 104 and the focus ring 112.

Accordingly, a method of processing a microelectronic device structure is disclosed and comprises disposing a microelectronic device structure in a processing system, the microelectronic device structure comprising one or more materials. A coolant is introduced into the processing system proximal to the microelectronic device structure and to a focus ring adjacent to the microelectronic device structure. One or more etch gas precursors is introduced into the processing system and the one or more etch gas precursors are excited to generate one or more etch plasmas. One or more of the etch plasmas exhibits a different diffusivity coefficient than other of the one or more etch plasmas. An inner region of the microelectronic device structure is exposed to at least one etch plasma and an outer region of the microelectronic device structure is exposed to at least one other etch plasma. The at least one etch plasma exhibits a diffusivity coefficient less than or equal to a diffusivity coefficient of the at least one other etch plasma. At least a portion of one or more materials of the microelectronic device structure is removed to form high aspect ratio openings and high aspect ratio features are formed in the high aspect ratio openings.

Accordingly, another method of processing a microelectronic device structure is disclosed and comprises disposing a microelectronic device structure in a processing system, the microelectronic device structure comprising one or more exposed materials. A coolant is introduced into the processing system to reduce a temperature of the microelectronic device structure and of a focus ring adjacent to the microelectronic device structure. One or more etch plasmas are formed from etch gas precursors in the processing system. One or more of the etch plasmas exhibit a different diffusivity coefficient than other of the one or more etch plasmas. At least a portion of the one or more materials of the microelectronic device structure is removed to form high aspect ratio openings and high aspect ratio features are formed in the high aspect ratio openings.

Accordingly, a system for processing a microelectronic device is disclosed and comprises a process chamber, an electrostatic chuck within the process chamber and configured to position a microelectronic device structure, and a focus ring adjacent to the electrostatic chuck and separated from the electrostatic chuck by a gap. A cooling system operably coupled to the electrostatic chuck and comprises inner apertures aligned with an inner region of the microelectronic device structure, outer apertures aligned with an outer region of the microelectronic device structure, and focus ring apertures aligned with the focus ring. A gas distribution showerhead is positioned above the electrostatic chuck and comprises inner channels, middle channels, and outer channels that are configured to flow one or more etch plasmas on the inner region and outer region of the microelectronic device structure. A side plenum is adjacent to the gas distribution showerhead and comprises side channels configured to flow an etch plasma on the focus ring and the outer region of the microelectronic device structure.

### EXAMPLES

### Example 1

The effect of etch gas composition and reducing a temperature difference between a microelectronic device structure and focus ring was analyzed. A control microelectronic device structure formed utilizing a conventional method (A) and a microelectronic device structure formed according to embodiments of the disclosure (B) were analyzed. A microelectronic device structure similar to the microelectronic device structure 300 was etched to form HAR openings 414 using the processing system and methods according to the embodiments of the disclosure (B). An outer region of the microelectronic device structure was exposed to a side etch plasma comprising C₄F₈ at a flow rate of 18 standard cubic centimeters per minute (sccm). The side etch plasma was introduced proximal to the outer region of the microelectronic device structure 400. A control microelectronic device structure having a similar structure to that of the microelectronic device structure 300 was also processed using a conventional method (A). An outer region of the control microelectronic device structure was exposed to an etch plasma comprising C₄F₈ and C₄F₆ at a flow rate of 10 sccm and 8 sccm, respectively. The side etch plasma was introduced proximal to the outer region of the control microelectronic device structure. The control microelectronic device structure and microelectronic device structure 400 were contacted with a coolant (e.g., helium) having a temperature and pressure of −30° C., 40 Torr(s). The C₄F₈ side etch plasma, under the conditions of the methods according to embodiments of the disclosure (B) exhibited a larger diffusivity coefficient than the etch plasma comprising C₄F₆ and C₄F₈ of the conventional method (A).

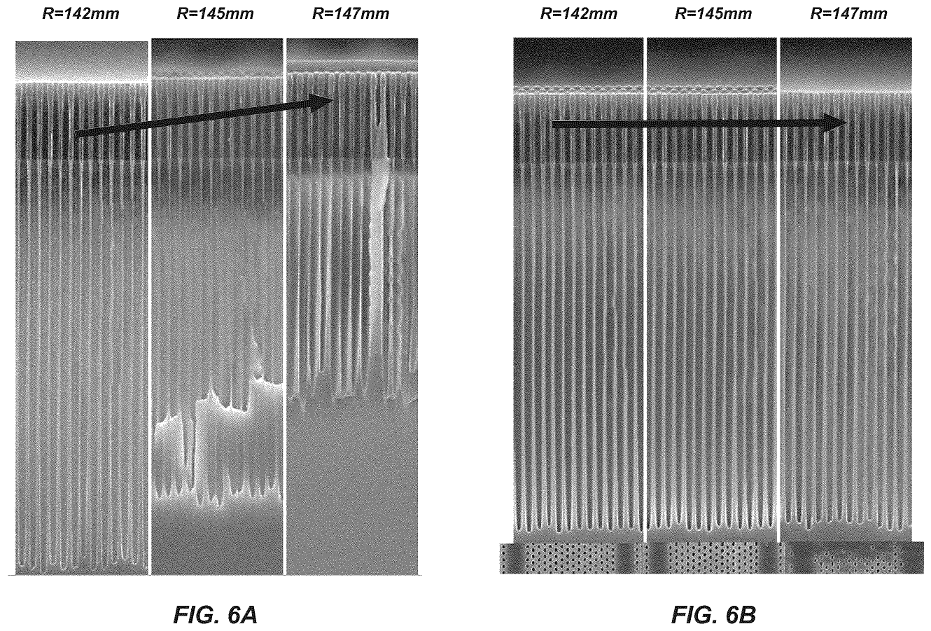

FIGS. 6A-6B illustrate a comparison between HAR openings of the control microelectronic device structure formed utilizing the conventional method (A) (FIG. 6A) and HAR openings 414 of the microelectronic device structure 400 formed according to the methods of the disclosure (B) (FIG. 6B). The alignment of the etch mask material in outer regions of the microelectronic device structure 400 (FIG. 6B) was improved relative to the alignment in the control microelectronic device structure (A) (FIG. 6A). The improved alignment was observed at an increasing radius R of the microelectronic device structure 400 greater than 142 mm when the methods according to the disclosure were utilized. As can be seen in FIG. 6B, a thickness of the etch mask material remaining in the outer region of the microelectronic device structure 400 decreased. Additionally, the bottoms 418 of the HAR openings 414 of the microelectronic device structure 400 demonstrated improved alignment compared to the control microelectronic device. As can be seen in FIG. 6B, the HAR openings 414 are more uniformly etched to the same depth at the radius R greater than 145 mm. Moreover, there is less twisting in the HAR openings 414 of the microelectronic device structure 400, particularly at the radius R greater than 145 mm.

### Example 2

The effect of etch gas composition and reducing a temperature difference between a microelectronic device structure and focus ring was analyzed. A control microelectronic device structure formed utilizing a conventional method (A) and a microelectronic device structure formed according to embodiments of the disclosure (B) were analyzed. A microelectronic device structure similar to the microelectronic device structure 300 was etched to form HAR openings 414 using the processing system and methods of the disclosure (B). An outer region of the microelectronic device structure was exposed to a side etch plasma comprising C₄F₈ and CH₂F₂ at a flow rate of 17 sccm and 5 sccm, respectively. The side etch plasma was introduced proximal to the outer region of the microelectronic device structure 400. A control microelectronic device structure having a similar structure to that of the microelectronic device structure 300 was also processed. An outer region of the control microelectronic device structure was exposed to a side etch plasma comprising C₄F₈ at a rate of 17.5 sccm. The side etch plasma was introduced proximal to the outer region of the control microelectronic device structure. The control microelectronic device structure and microelectronic device structure 400 were contacted by a coolant (e.g., helium) maintained at a temperature and pressure of −30° C., 40 Torr(s). The CH₂F₂ plasma, under the conditions of the processing method of the disclosure, exhibited a larger diffusivity coefficient than the C₄F₈.

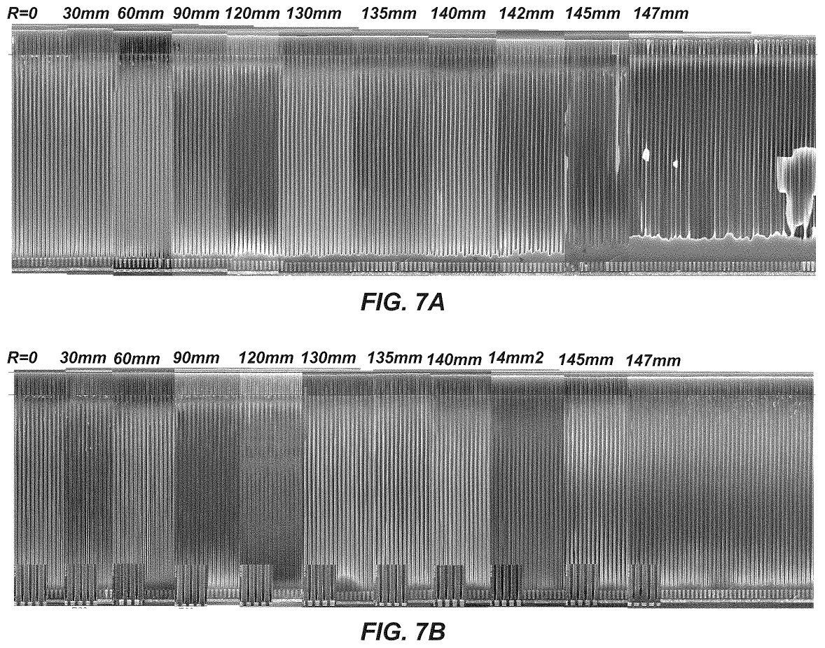

As shown in FIGS. 7A-7B, a comparison between the bottoms 418 of the HAR openings 414 of the microelectronic device structure 400 (FIG. 7B) and the control microelectronic device structure (FIG. 7A) demonstrated improved alignment of the bottoms 418 of HAR openings 414 in the microelectronic device structure 400. These openings were more uniformly etched to the same depth across the microelectronic device structure 400 regardless of the distance from the center of the microelectronic device structure 400. Particularly, alignment of the bottoms 418 of the HAR openings 414 in the outer region of the microelectronic device structure improved in that the HAR openings were more uniformly etched to the same depth at the radius R greater than 147 mm.

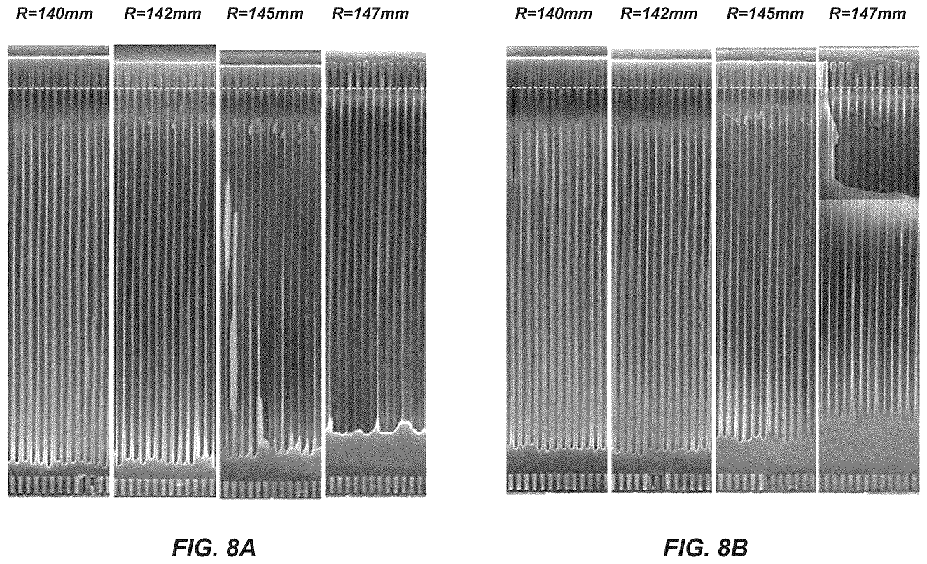

As shown in FIGS. 8A-8B, a comparison between the bottoms 418 of the HAR openings 414 of the microelectronic device structure 400 (FIG. 8B) and the control microelectronic device structure (FIG. 8A) demonstrated a reduction in twisting of the HAR openings 414 in the outer region of the microelectronic device structure 400, at the radius greater than 145 mm.

Without being bound by any theory, it is believed that exposing the outer region of the microelectronic device structure to a side etch plasma exhibiting a diffusivity coefficient greater than an etch plasma contacting the inner region of the microelectronic device structure, reducing the temperature difference between the microelectronic device structure and the focus ring, and reducing the temperature difference between the inner and outer regions of the microelectronic device structure increase the uniformity of etch depth/rate in the outer region of the microelectronic device structure relative to the inner region of the microelectronic device structure, improve alignment of the etch mask and the alignment of the bottoms of the HAR openings, and reduce twisting/bowing in the HAR openings in the outer region of the microelectronic device structure.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A method of processing a microelectronic device structure, comprising:
disposing a microelectronic device structure in a processing system, the microelectronic device structure comprising one or more materials;
introducing a coolant into the processing system proximal to the microelectronic device structure and to a focus ring adjacent to the microelectronic device structure;
introducing one or more etch gas precursors into the processing system;
exciting the one or more etch gas precursors to generate one or more etch plasmas, one or more of the etch plasmas exhibiting a different diffusivity coefficient than other of the one or more etch gas precursors;
exposing an inner region of the microelectronic device structure to at least one etch plasma and an outer region of the microelectronic device structure to at least one other etch plasma, the at least one etch plasma exhibiting a diffusivity coefficient less than or equal to a diffusivity coefficient of the at least one other etch plasma;
removing at least a portion of one or more materials of the microelectronic device structure to form high aspect ratio openings; and
forming high aspect ratio features in the high aspect ratio openings.

2. The method of claim 1, wherein introducing a coolant into the processing system proximal to the microelectronic device structure and a focus ring comprises reducing a temperature difference between the microelectronic device structure and the focus ring.

3. The method of claim 2, wherein reducing a temperature difference between the microelectronic device structure and the focus ring comprises maintaining a temperature of the microelectronic device structure between about 20° C. and about 60° C. and the temperature of the focus ring between about 40° C. and about 160° C.

4. The method of claim 1, wherein introducing a coolant into the processing system proximal to the microelectronic device structure and a focus ring comprises reducing a temperature difference between an inner region and an outer region of the microelectronic device structure.

5. The method of claim 4, wherein reducing a temperature difference between the microelectronic device structure and the focus ring comprises maintaining a temperature of the microelectronic device structure between about 20° C. and about 40° C. and a temperature of the focus ring between about 40° C. and about 60° C.

6. The method of claim 1, wherein introducing one or more etch gas precursors into the processing system comprises introducing etch gas precursors comprising a fluorocarbon, a hydrofluorocarbon, SF₆, NF₃, HBr, or a combination thereof into the processing system.

7. The method of claim 1, wherein exposing an inner region of the microelectronic device structure to at least one etch plasma and an outer region of the microelectronic device structure to at least one other etch plasma comprises exposing the inner region of the microelectronic device structure to a first etch plasma and a second etch plasma and the outer region of the microelectronic device structure to a third etch plasma and a side etch plasma, the side etch plasma exhibiting a greater diffusivity coefficient than the first, second, and third etch plasmas.

8. The method of claim 7, wherein exposing the outer region of the microelectronic device structure to a third etch plasma and a side etch plasma further comprises flowing the third etch plasma and side etch plasma into a gap between the focus ring and the microelectronic device structure and flowing the side etch plasma over the focus ring.

9. The method of claim 8, wherein flowing the third etch plasma and side etch plasma into a gap between the focus ring and the microelectronic device structure and flowing the side etch plasma over the focus ring increase a concentration of radicals on the outer region of the microelectronic device structure and in the gap.

10. The method of claim 1, wherein exposing an inner region of the microelectronic device structure to at least one etch plasma and an outer region of the microelectronic device structure to at least one other etch plasma comprises exposing the inner region of the microelectronic device structure to a first etch plasma and the outer region of the microelectronic device structure to a third etch plasma and a side etch plasma, the side etch plasma exhibiting a greater diffusivity coefficient than the first and third etch plasmas.

11. A method of processing a microelectronic device structure, comprising:
disposing a microelectronic device structure in a processing system, the microelectronic device structure comprising one or more exposed materials;
introducing a coolant into the processing system to reduce a temperature of the microelectronic device structure and of a focus ring adjacent to the microelectronic device structure;
forming one or more etch plasmas from etch gas precursors in the processing system, one or more of the etch plasmas exhibiting a different diffusivity coefficient than other of the one or more etch plasmas;
exposing an inner region of the microelectronic device structure to at least one etch plasma and an outer region of the microelectronic device structure to at least one other of the etch plasmas, the at least one etch plasma exhibiting a diffusivity coefficient relatively less than or equal to a diffusivity coefficient of the at least one other of the etch plasmas;
removing at least a portion of one or more materials of the microelectronic device structure to form high aspect ratio openings; and
forming high aspect ratio features in the high aspect ratio openings.

12. The method of claim 11, wherein introducing a coolant into the processing system comprises decreasing a temperature difference between the microelectronic device structure and the focus ring and between an inner region and an outer region of the microelectronic device structure.

13. The method of claim 11, further comprising flowing the at least one other of the etch plasmas between the outer region of the microelectronic device structure and the focus ring.

14. A system for processing a microelectronic device, comprising:
a process chamber;
an electrostatic chuck within the process chamber and configured to position a microelectronic device structure;
a focus ring adjacent to the electrostatic chuck and separated from the electrostatic chuck by a gap;
a cooling system operably coupled to the electrostatic chuck, the cooling system comprising:
inner apertures aligned with an inner region of the microelectronic device structure;
outer apertures aligned with an outer region of the microelectronic device structure; and
focus ring apertures aligned with the focus ring;
a gas distribution showerhead positioned above the electrostatic chuck and comprising inner channels, middle channels, and outer channels, the channels configured to flow one or more etch plasmas on the inner region and outer region of the microelectronic device structure; and
a side plenum adjacent to the gas distribution showerhead, the side plenum comprising side channels configured to flow an etch plasma on the focus ring and the outer region of the microelectronic device structure.

15. The system of claim 14, wherein the inner channels and middle channels are configured to substantially align with a top surface of the inner region of the microelectronic device structure, and the outer channels are configured to substantially align with a top surface of the outer region of the microelectronic device structure.

16. The system of claim 14, wherein the side channels are configured to substantially align with the focus ring and a top surface of the outer region of the microelectronic device structure.

17. The system of claim 14, wherein the cooling system is configured to flow a coolant onto inner and outer regions of the microelectronic device structure and the focus ring.

18. The system of claim 14, wherein the cooling system is configured to maintain a temperature of the microelectronic device structure between about 20° C. and about 60° C. and a temperature of the focus ring between about 40° C. and about 160° C.

19. The system of claim 14, wherein the cooling system is configured to maintain a temperature of the microelectronic device structure between about 20° C. and about 40° C. and a temperature of the focus ring between about 40° C. and about 60° C.

20. The system of claim 14, wherein the cooling system is configured to maintain a temperature of the microelectronic device structure at about 30° C. and a temperature of the focus ring at about 50° C.
